(19) United States
(12) Patent Application Publication
(10) Pub. No.: US 2026/0247586 A1
(43) Pub. Date: Aug. 20, 2026

(54) SYSTEMS FOR A THERMAL MANAGEMENT DEVICE

(71) Applicant: Dana Canada Corporation, Oakville (CA)

(72) Inventors: Pierre PÉGART, Oakville (CA); Andrei CATUNEANU, Burlington (CA)

(21) Appl. No.: 19/057,776

(22) Filed: Feb. 19, 2025

(51) Int. Cl. H05K 7/20

(52) U.S. Cl. CPC H05K 7/209

(57) ABSTRACT

Systems are provided for a heat exchanger. In one example, a heat exchanger includes a first support and a second support arranged on opposite sides of a heat transfer element and in face-sharing contact with a core plate. The first support and the second support are flush with and pressed against surfaces of the core plate.

### TECHNICAL FIELD

The present description relates generally to mounting a heat exchanger to electronic components.

### BACKGROUND AND SUMMARY

Heat generating devices, such as power electronic devices, may be coupled to a heat exchanger to remove heat and lower an operating temperature of the heat generating device(s). In some examples, the power electronic devices or modules are provided with opposite planar faces along which cooling may be provided. Such devices may be cooled by contacting one or both of the opposite planar faces of a heat exchanger. In order to increase thermal contact with the planar face of the power electronic device, the heat exchanger may include a planar surface along which it contacts the power electronic device, and a thin layer of thermal interface material (TIM) may be provided between the heat sink and the planar face of the power electronic device. In some examples, a fluid such as coolant, oil, or refrigerant may be circulated within the heat exchanger.

In some examples, cooling assemblies for power electronics devices may include elements for joining first and second heat exchangers to the opposite sides of a power electronics device in a sandwich arrangement. Contact between the power electronic device and the heat exchanger may be increased by compressing the first and second heat exchangers around the device. The compression may apply forces to the structures of the heat exchangers, which may reduce a longevity thereof. For example, the heat exchanger may include a heat transfer element therein, where a peripheral portion of the heat exchanger not including the heat transfer element may be unsupported and subject to an increased likelihood of degradation due to the compressive forces.

In one example, the issues described above may be at least partially solved by a heat exchanger including a first support and a second support arranged on opposite sides of a heat transfer element and in face-sharing contact with a core plate. In this way, the first support and the second support may provide additional support to a periphery of the heat exchanger.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE FIGURES

The above, as well as other advantages of the present disclosure, will become readily apparent to those skilled in the art from the following detailed description when considered in light of the accompanying drawings in which:

FIG. 1 is a schematic depiction of an example vehicle powertrain;

FIG. 2 is an embodiment of a cooling system including multiple heat exchangers;

FIG. 3 is an exploded view of an example heat exchanger;

FIG. 4A shows an example of a core plate of a heat exchanger without supports;

FIG. 4B shows an example of a core plate of the heat exchanger with supports;

FIG. 5 shows an example of a support of the heat exchanger;

FIG. 6 shows a cross-section of the support nested with the core plate of the heat exchanger;

FIG. 7 shows an indent of the core plate that interfaces with the support;

FIGS. 8A, 8B, and 8C show an alternate embodiment of the core plate and corresponding supports; and

FIG. 9 shows an alternate embodiment of the supports of the heat exchanger.

### DETAILED DESCRIPTION

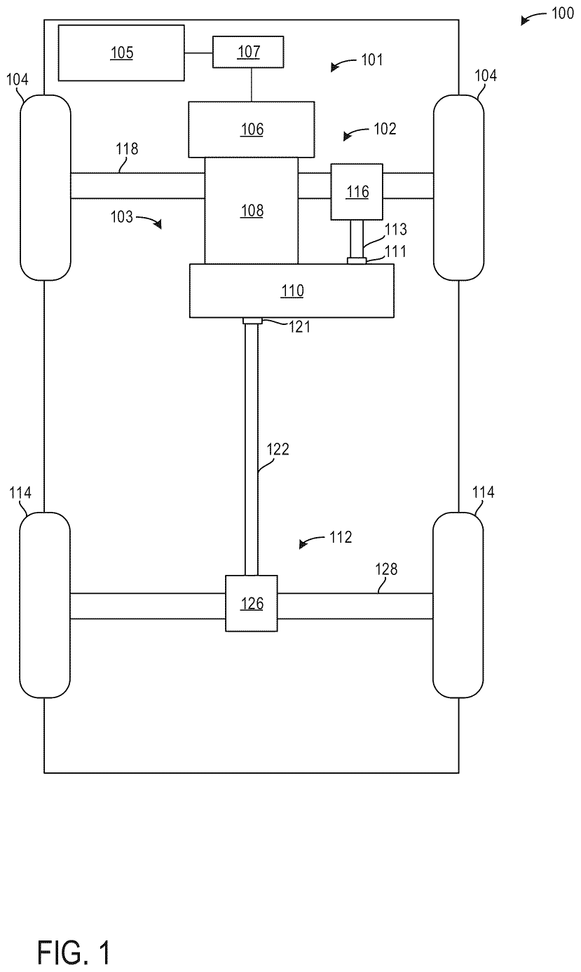

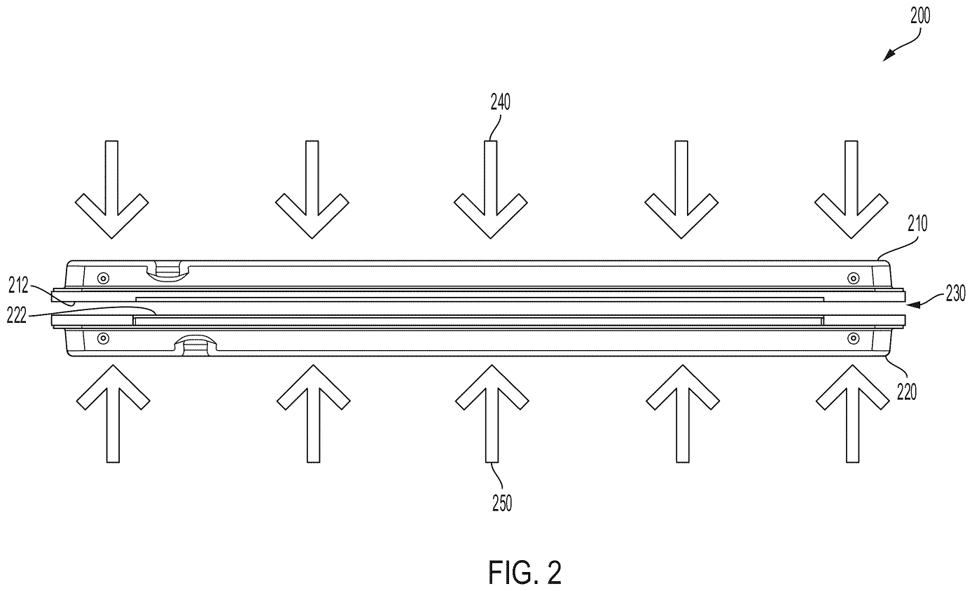

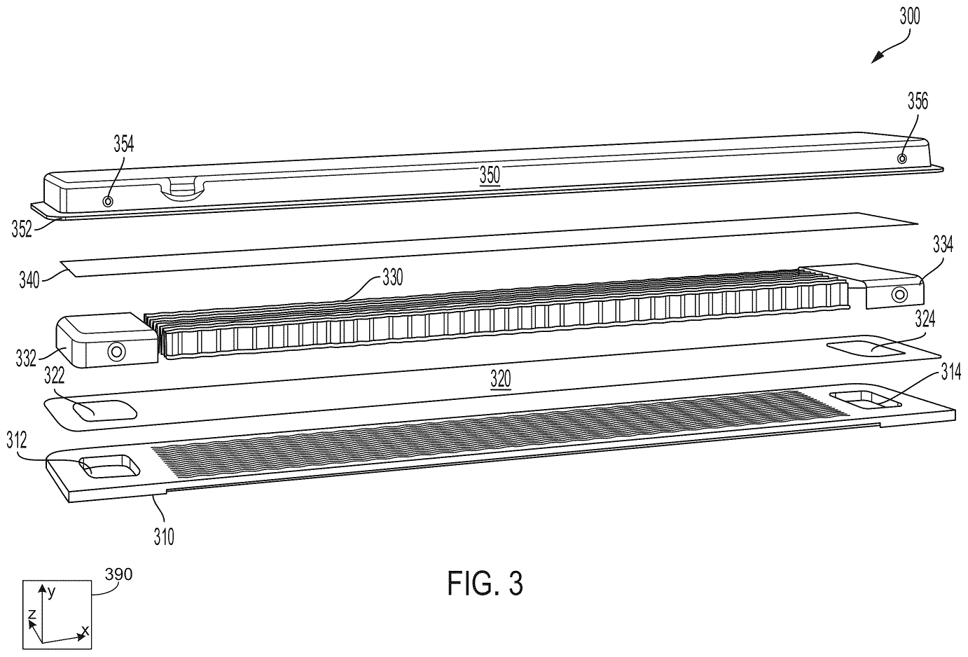

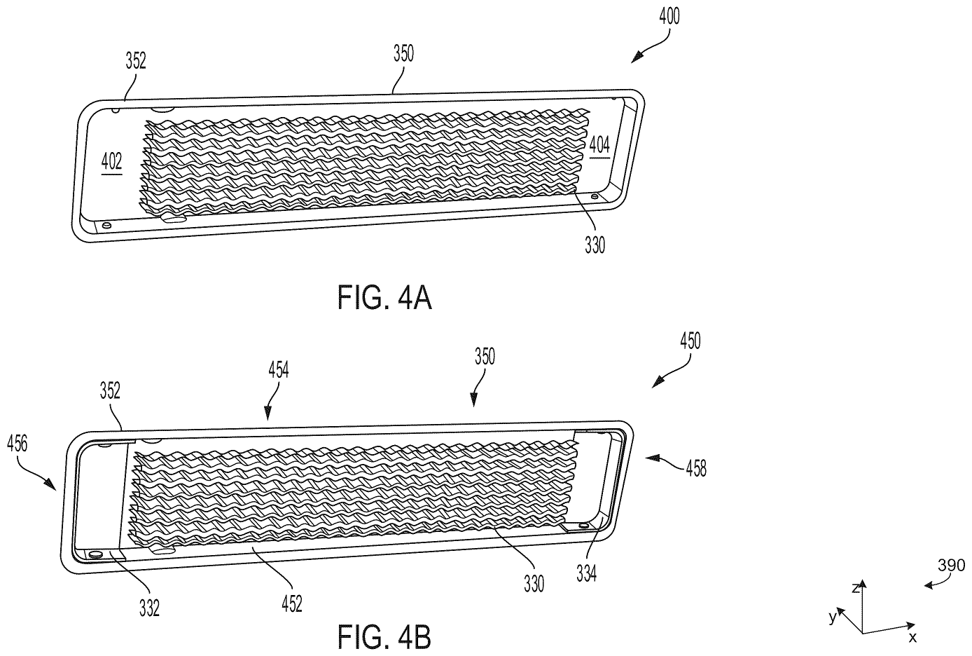

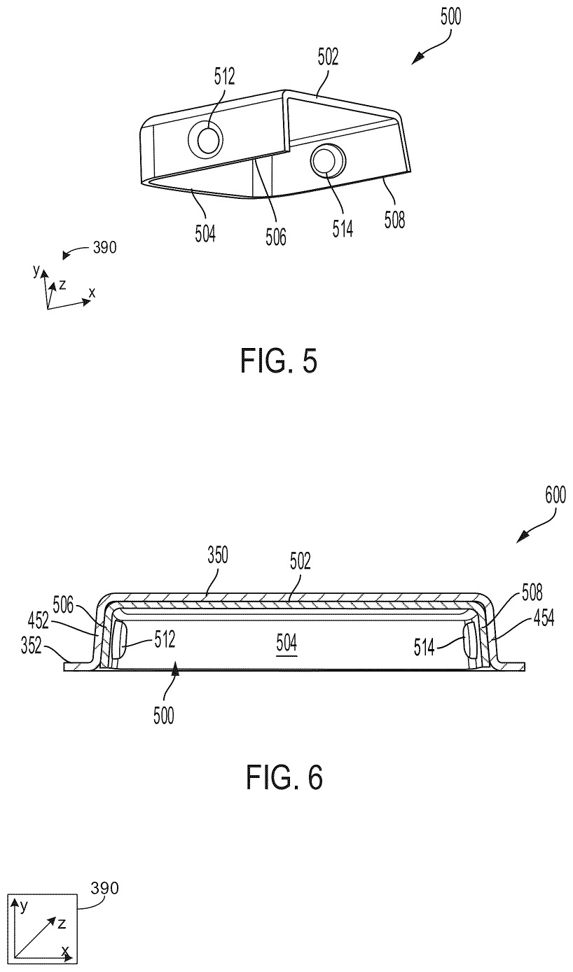

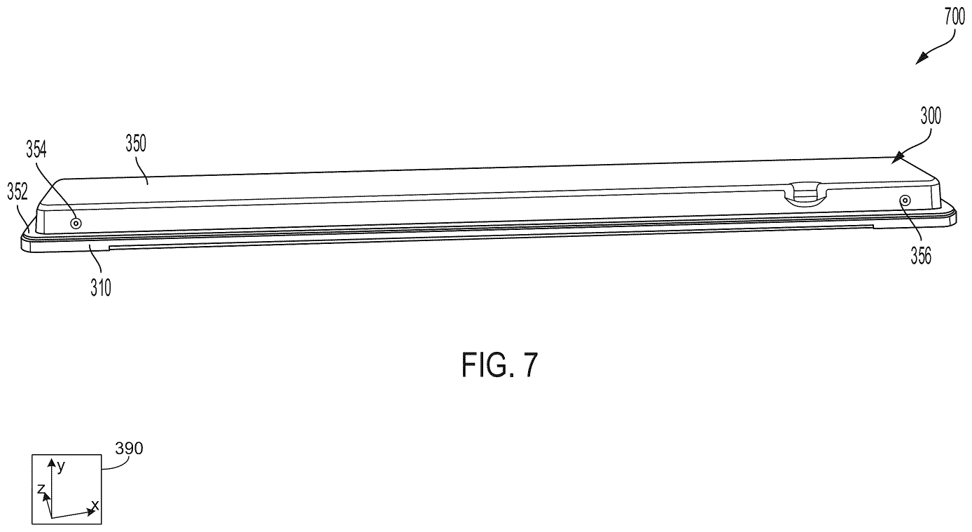

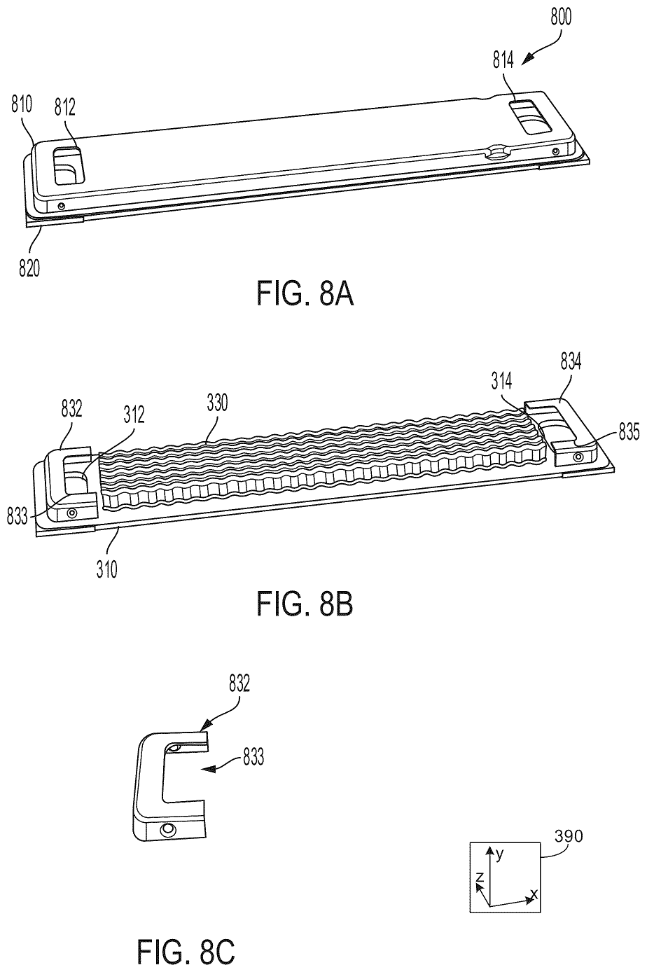

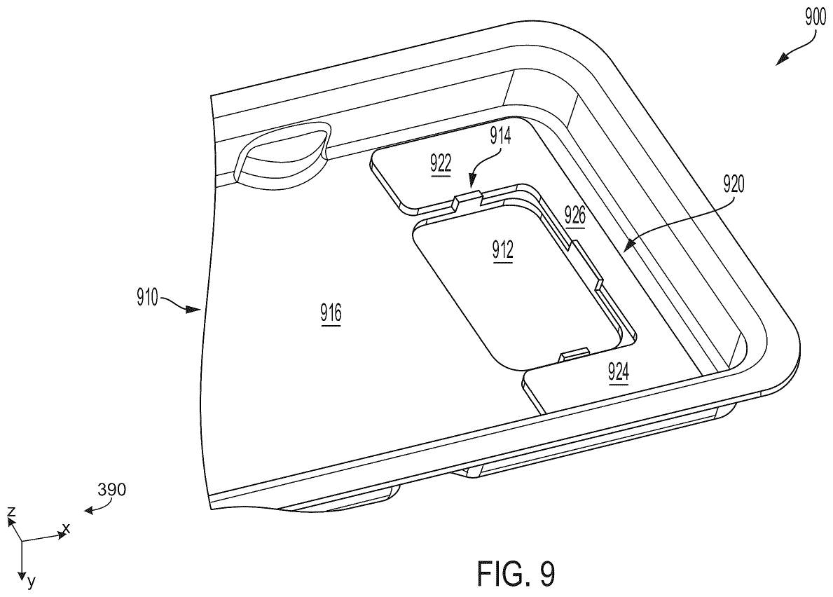

The following description relates to systems for a power electronics cooling assembly FIG. 1 is a schematic depiction of an example vehicle powertrain. FIG. 2 is an embodiment of a cooling system including multiple heat exchangers. FIG. 3 is an exploded view of an example heat exchanger. FIG. 4A shows a prior art example of a core plate of a heat exchanger. FIG. 4B shows an example of a core plate of the heat exchanger according to an embodiment of the present disclosure. FIG. 5 shows an example of a support for a peripheral portion of the heat exchanger. FIG. 6 shows a cross-section of the support nested with the core plate of the heat exchanger. FIG. 7 shows an indent of the core plate that interfaces with the support. FIGS. 8A, 8B, and 8C show an alternate embodiment of the core plate and corresponding supports. FIG. 9 shows an alternate embodiment of the supports of the heat exchanger.

FIGS. 1-9 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example. It will be appreciated that one or more components referred to as being “substantially similar and/or identical” differ from one another according to manufacturing tolerances (e.g., within 1-5% deviation). FIGS. 2-9 are shown approximately to scale, however, other dimensions may be used if desired.

Turning now to FIG. 1, a vehicle 100 is shown comprising a powertrain 101 and a drivetrain 103. The powertrain comprises a prime mover 106 and a transmission 108. The prime mover 106 may be an internal combustion engine or an electric motor, for example, and is operated to provide rotary power to the transmission 108. The transmission 108 may be any type of transmission, such as a manual transmission, an automatic transmission, or a continuously variable transmission. The transmission 108 receives the rotary power produced by the prime mover 106 as an input and outputs rotary power to the drivetrain 103 in accordance with a selected gear or setting.

The prime mover 106 may be powered via energy from an energy storage device 105. In one example, the energy storage device 105 is a battery configured to store electrical energy. An inverter 107 may be arranged between the energy storage device 105 and the prime mover 106 and configured to adjust direct current (DC) to alternating current (AC). The inverter 107 may include a variety of components and circuitry with thermal demands that effect an efficiency of the inverter. The inverter 107, and other electronic components of the vehicle 100, may include a cooling arrangement configured to meet the thermal demands of the components. An example cooling arrangement is shown in FIGS. 2-9.

The vehicle 100 may be a commercial vehicle, light, medium, or heavy duty vehicle, a passenger vehicle, an off-highway vehicle, and sport utility vehicle. Additionally or alternatively, the vehicle 100 and/or one or more of its components may be in industrial, locomotive, military, agricultural, and aerospace applications. In one example, the vehicle 100 is an electric vehicle.

In some examples, such as shown in FIG. 1, the drivetrain 103 includes a first axle assembly 102 and a second axle assembly 112. The first axle assembly 102 may be configured to drive a first set of wheels 104, and the second axle assembly 112 may be configured to drive a second set of wheels 114. In one example, the first axle assembly 102 is arranged near a front of the vehicle 100 and thereby comprises a front axle, and the second axle assembly 112 is arranged near a rear of the vehicle 100 and thereby comprises a rear axle. The drivetrain 103 is shown in a four-wheel drive configuration, although other configurations are possible. For example, the drivetrain 103 may include a front-wheel drive, a rear-wheel drive, or an all-wheel drive configuration. Further, the drivetrain 103 may include one or more tandem axle assemblies. As such, the drivetrain 103 may have other configurations without departing from the scope of this disclosure, and the configuration shown in FIG. 1 is provided for illustration, not limitation. Further, the vehicle 100 may include additional wheels that are not coupled to the drivetrain 103.

In some four-wheel drive configurations, such as shown in FIG. 1, the drivetrain 103 includes a transfer case 110 configured to receive rotary power output by the transmission 108. A first driveshaft 113 is drivingly coupled to a first output 111 of the transfer case 110, while a second driveshaft 122 is drivingly coupled to a second output 121 of the transfer case 110. The first driveshaft 113 (e.g., a front driveshaft) transmits rotary power from the transfer case 110 to a first differential 116 of the first axle assembly 102 to drive the first set of wheels 104, while the second driveshaft 122 (e.g., a rear driveshaft) transmits the rotary power from the transfer case 110 to a second differential 126 of the second axle assembly 112 to drive the second set of wheels 114. For example, the first differential 116 is drivingly coupled to a first set of axle shafts 118 coupled to the first set of wheels 104, and the second differential 126 is drivingly coupled to a second set of axle shafts 128 coupled to the second set of wheels 114. It may be appreciated that each of the first set of axle shafts 118 and the second set of axle shafts 128 may be positioned in a housing.

In some examples, additionally or alternatively, the vehicle 100 may be a hybrid vehicle including both an engine an electric machine each configured to supply power to one or more of the first axle assembly 102 and the second axle assembly 112. For example, one or both of the first axle assembly 102 and the second axle assembly 112 may be driven via power originating from the engine in a first operating mode where the electric machine is not operated to provide power (e.g., an engine-only mode), via power originating from the electric machine in a second operating mode where the engine is not operated to provide power (e.g., an electric-only mode), and via power originating from both the engine and the electric machine in a third operating mode (e.g., an electric assist mode). As another example, one or both of the first axle assembly 102 and the second axle assembly 112 may be an electric axle assembly configured to be driven by an integrated electric machine.

Turning now to FIG. 2, it shows an exemplary cooling arrangement 200 including a first heat exchanger 210 and a second heat exchanger 220. A gap 230 between the first heat exchanger 210 and the second heat exchanger 220 may correspond to a region in which at least one electronic module or component of a vehicle such as vehicle 100 may be arranged. A heat transfer surface 212 of the first heat exchanger 210 may face the gap 230. A heat transfer surface 222 of the second heat exchanger 220 may face the gap 230 and the first heat exchanger 210. Compressive forces, shown by arrows 240 and 250, may be applied to increase contact between the electronic module arranged in the gap 230, the first heat exchanger 210, and the second heat exchanger 220. The compressive forces may further enhance sealing of the heat exchangers and adjoining components.

As described above, certain areas of the heat exchangers, such as the inlet and outlet ports, may be prone to deformation due to the compressive forces. Embodiments of the heat exchangers described herein, such as the embodiments described with respect to FIGS. 3-9, include features that reduce the likelihood of deformation.

While two heat exchangers are shown surrounding the gap in which an electronic device may be placed, it will be appreciated that any number of heat exchangers may be used without departing from the scope of the present disclosure. For example, a single heat exchanger may be used wherein the electronic device(s) include a heat exchanger on only one side.

Turning now to FIG. 3, it shows an exploded view of components of an example heat exchanger 300, which may be a non-limiting example of first heat exchanger 210 and/or second heat exchanger 220 of FIG. 2. The heat exchanger 300 may be a fluid heat exchanger configured to conduct coolant, lubricant, or refrigerant. An axis system 390 may include three axes, namely an x-axis parallel to a horizontal direction, a y-axis parallel to a vertical direction, and a z-axis normal to each of the x-and y-axes. The heat exchanger 300 may include a baseplate 310. The baseplate 310 may include a rectangular shape planar with an x-z plane. The baseplate 310 may include a first port 312 and a second port 314. The first port 312 and the second port 314 may correspond to inlet and outlet ports of the heat exchanger 300. The baseplate 310 may include a non-smooth surface between the first port 312 and the second port 314, such as a textured surface. In other examples, the baseplate 310 may include a smooth surface between the first port 312 and the second port 314.

A first shim 320 may be arranged between the baseplate 310 and a heat transfer element 330. The first shim 320 may include a rectangular shape similar to the baseplate 310. The first shim 320 may further include a first opening 322 corresponding to the first port 312 of the baseplate 310 and a second opening 324 corresponding to the second port 314 of the baseplate 310. The first shim 320 may press against a surface of the baseplate 310 opposite a heat transfer surface of the baseplate 310, wherein the surface faces an interior volume of the heat exchanger 300 and the heat transfer surface faces an exterior of the heat exchanger 300.

The heat transfer element 330 may include a plurality of fluids passageways, wavy fins, or other elements that increase a heat transfer of the heat exchanger 300. The heat transfer element 330 may include where the plurality of fluid passageways extends along the x-axis. In this way, a surface area of the heat transfer element 330 is increased.

In some examples, the heat transfer element 330 may be omitted. In such examples, a heat transfer enhancement feature and structural support may be included in a similar region to the heat transfer element 330. The heat transfer enhancement feature may include one or more of dimples, ribs, and pins shaped in one or more of the baseplate 310 and a core plate 350.

The heat exchanger 300 may include at least one support to prevent a peripheral portion of the heat exchanger 300 not including the heat transfer element 330 from deforming. Specifically, the heat exchanger 300 may include a first support 332 and a second support 334. The first support 332 and the second support 334 may be identical in size and shape. Additionally or alternatively, the first support 332 may be different than the second support in size and/or shape. The first support 332 and the second support 334 may include a plurality of linear surfaces that form a cup-shape or a scoop shape. A structure of the first support 332 and the second support 334 is described in greater detail with respect to FIG. 5. The first support 332 may be arranged at a first end of the heat transfer element 330 and the second support 334 may be arranged at a second end of the heat transfer element 330.

The first support 332 and the second support 334 are separate pieces. That is to say, the heat transfer element 330 may be arranged between and separate the first support 332 from the second support 334. The first support 332 may be configured as a single-piece. Similarly, the second support 334 may be configured as a single-piece. In some embodiments, the first support 332 and the second support 334 may be integrated into a single-piece or may be integrated into a body of the core plate 350.

A second shim 340 may be arranged between the heat transfer element 330 and the core plate 350. The second shim 340 may include a rectangular shape identical to the first shim 320. The second shim 340 may not include openings, in one example. Alternatively, if ports are arranged in the core plate 350, then the second shim 340 may include openings corresponding to the ports. In other examples, the first shim 320 and/or the second shim 340 may be omitted from the heat exchanger 300. In some examples, additionally or alternatively, the ports may be arranged on only the core plate 350 and the baseplate 310 may be a single solid piece free of ports.

The core plate 350 may include a box shape. In one example, the core plate 350 may include a shape configured to house the first shim 320, the heat transfer element 330, the first support 332, the second support 334, and the second shim 340. The core plate 350 may further include a lip 352 that may be pressed against a surface of the baseplate 310. In one example, the lip 352 of the core plate 350 may be joined (e.g., sealed) against the surface of the baseplate 310 so that fluid is contained within the heat exchanger 300 and does not leak.

The core plate 350 may include a first pair of protrusions and a second pair of protrusions. The first pair of protrusions may include a first protrusion 354 and the second pair of protrusions may include a second protrusion 356. The pairs of protrusions may be provided once the first support 332 and the second support 334 are inserted into a periphery of the core plate 350.

The baseplate 310 and the core plate 350 may be configured to join and house the first shim 320, the second shim 340, the heat transfer element 330, the first support 332, and the second support 334. The ports 312, 314 of the baseplate 310 may be configured to control fluid flow into the heat exchanger 300, wherein fluid may only enter and leave the heat exchanger 300 via the ports.

Turning now to FIG. 4A, it shows an embodiment 400 of the core plate 350 coupled to the heat transfer element 330. The first support 332 and the second support 334 are not installed in the core plate 350 in the example of the embodiment 400. As illustrated, embodiment 400 includes a periphery region 402 and a periphery region 404 of the core plate 350 where the heat transfer element is not arranged. The first support 332 and the second support 334 may be arranged in the periphery regions 402 and 404 to provide support to the core plate 350 (e.g., to prevent the core plate 350 from deforming under compressive forces). The first support 332 and the second support 334 may be configured to maintain product performance by not affecting fluid flow. By including first support 332 and the second support 334, a gauge of the core plate 350 may be maintained, which may decrease manufacturing costs relative to a solution including increasing a thickness of the core plate 350. The first support 332 and the second support 334 may be used with a variety of materials, including aluminum and/or copper.

Turning now to FIG. 4B, it shows an embodiment 450 of the core plate 350 with the first support 332 and the second support 334 coupled thereto in the periphery regions 402 and 404. The first support 332 may be arranged at a first short side 456 and the second support 334 may be arranged at a second short side 458, opposite the first short side 456. The first support 332 may be shaped to press against and be held flush with a surface of the core plate 350. Similarly, the second support 334 may be shaped to press against and be held flush with the surface of the core plate 350. The first support 332 and the second support 334 are arranged on opposite sides of the heat transfer element 330.

The first support 332 may be in face-sharing contact with an entirety of the first short side 456 of the core plate 350. The first support 332 may be in face-sharing contact with a portion of the first long side 452 and the second long side 454. The second support 334 may be in face-sharing contact with an entirety of the second short side 458 of the core plate 350. The second support 334 may be in face-sharing contact with a portion of the first long side 452 and the second long side 454.

A long axis of the first support 332 may be parallel to a long axis of the second support 334. The long axis of the first support 332 and the second support 334 may be normal to a long axis of the core plate 350. Additionally or alternatively, the long axis of the first support 332 and the second support 334 may be normal to a long axis of the heat transfer element 330.

Turning now to FIG. 5, it shows an example of a support 500. The support 500 may be identical to each of the first support 332 and the second support 334. The support 500 may include a top surface 502, a long side 504, a first short side 506, and a second short side 508.

The top surface 502 may include a rectangular shape. The top surface 502 may be smooth on both sides, namely a side that faces the core plate and a side that faces the baseplate. The top surface 502 may be in contact with each of the long side 504, the first short side 506, and the second short side 508. The support 500 may not include a side opposite the top side 502 such that the support 500 is open.

The long side 504 may include a rectangular shape. A shape of the long side 504 may be complementary to a shape of the first short side 456 of the core plate 350 of FIG. 4B. The long side 504 may be smooth on both sides, namely a side that faces the first short side of the core plate and a side the faces the heat transfer element. The support 500 may not include a side opposite the long side 504.

The first short side 506 and the second short side 508 may be identical to one another in size and shape. The first short side 506 and the second short side 508 may include a rectangular shape. The rectangular shape of the first short side 506 and the second short side 508 may include a length less than a length of the long side 504. In one example, the length of the first short side 506 and the second short side 508 may correspond to a difference between a length of the long sides (e.g., first long side 452 and second long side 454 of FIG. 4B) of the core plate and a longitudinal length of the heat transfer element 330 of FIG. 3. The first short side 506 may contact the long side 504 and the top surface 502 at a first end. The second short side 508 may contact the long side 504 and the top surface 502 at a second end, the second end opposite the first end.

The first short side 506 may include a first indentation 512. The first indentation 512 may be configured to receive the first protrusion 354 or the second protrusion 356. The first indentation 512 may include a circular shape. However, the first indentation 512 may include other shapes to match a shape of the protrusion of the core plate.

The second short side 506 may include a second indentation 514. The second indentation 514 may be identical to and aligned with the first indentation 512. The second indentation may be configured to receive the other of the first pair of protrusions or the second pair of protrusions. That is to say, if the first protrusion 354 is pressed into the first indentation 512, then the other protrusion of the first pair of protrusions, which includes the first protrusion, may be pressed into the second indentation 514.

The indentations and the protrusions may be configured to retain the support 500 against the core plate. In one example, the indentations and the protrusions may be shaped after the support 500 is inserted into the core plate. As such, the surfaces of the indentations and the core plate may be smooth prior to being coupled to one another. By doing this, a brazing process or other coupling process may be simplified, which may increase production efficiency.

Turning now to FIG. 6, it shows a cross-sectional view 600 of the support 500 pressed against and coupled to the core plate 350. As illustrated, the surfaces of the support 500 and the core plate 350 are flush with one another such that gaps are not present. In one example, the surfaces of the support 500 and the core plate 350 may be sealed together such that fluid may not flow between the support 500 and the core plate 350. The protrusions of the core plate 350 are nested into the indentations of the support 500 in order to retain the support 500 against the core plate 350 prior to brazing.

Turning now to FIG. 7, it shows an assembled view 700 of the heat exchanger 300. As illustrated, only an outer edge of the baseplate 310 and the core plate 350 are exposed. The heat transfer element, the supports, and the shims are sealed within the baseplate 310 and the core plate 350.

Turning now to 8A, it shows an alternative embodiment of a heat exchanger 800 including ports arranged in a core plate 810. In one example, a shape of the core plate 810 is identical to the core plate 350 of FIGS. 3, 4A, 4B, and 7, except that the core plate 810 includes cutouts corresponding to ports. In one example, the core plate 810 includes a first port 812 and a second port 814, where one port is an inlet port and the other port is an outlet port.

Turning now to FIG. 8B, it shows the heat exchanger 800 with the core plate 810 removed, thereby exposing the heat transfer element 330, a first support 832, and a second support 834. The first support 832 and the second support 834 may be identical to the first support 332 and the second support 334 of FIG. 3, except that the first support 832 includes a first cutout 833 in a first top surface of first support 832 and the second support 834 includes a second cutout 835 in a second top surface of second support 834. In one example, the first and second top surfaces of the first support 832 and the second support 834, respectively, may include a U-shape. A detailed view of the first support 832 and the first cutout 833 is shown in FIG. 8C. The first cutout 833 may align with the first port 812 and the first port 312. The second cutout 835 may align with the second port 814 and the second port 314. As such, the first cutout 833 and the second cutout 835 may be configured to facilitate fluid flow and provide support to the peripheral regions of the heat exchanger 800.

Turning now to FIG. 9, it shows an embodiment 900 of a core plate 910 and a support 920. The core plate 910 may be shaped similarly to core plate 810 of FIG. 8A in that the core plate 910 includes ports. A plurality of tabs 914 is illustrated around a first port 912 of the core plate 910. The plurality of tabs 914 is configured to retain the support 920. In the example of FIG. 9, the support 920 is planar and flush with a top surface 916 of the core plate 910. That is to say, the support 920 is spaced away from short and long sides of the core plate 910.

The support 920 may include a C-shape, a U-shape, or other similar shape. The support 920 may include a first body 922, a second body 924, and a third body 926. The support 920 may be a single piece. The first body 922 may be identical to the second body 924 in size and shape. The first body 922 and the second body 924 may include a rectangular shape, where a long axis of the first body 922 and the second body 924 is parallel to a long axis of the core plate 910. The first body 922 and the second body 924 may be spaced on opposite sides of port 912.

The third body 926 may include a rectangular shape different than the first body 922 and the second body 924. A long axis of the third body 926 may be normal to long axes of the first body 922, the second body 924, and the core plate 910. The third body 926 may join with the first body 922 and the second body 924. The first body 922, the second body 924, and the third body 926 may be shaped to provide a border around the first port 912 and support the periphery of the core plate 910 where the heat transfer element is not arranged.

The disclosure also provides support for a heat exchanger, comprising: a first support and a second support arranged on opposite sides of a heat transfer element and in face-sharing contact with a core plate. In a first example of the system, the first support and the second support are retained against the core plate via indentations. In a second example of the system, optionally including the first example, the first support and the second support are retained via a plurality of tabs against the core plate. In a third example of the system, optionally including one or both of the first and second examples, the first support and the second support are brazed to the core plate. In a fourth example of the system, optionally including one or more or each of the first through third examples, the first support and the second support are identical in size and shape. In a fifth example of the system, optionally including one or more or each of the first through fourth examples, the first support and the second support comprise a cutout corresponding to ports of the core plate. In a sixth example of the system, optionally including one or more or each of the first through fifth examples the first support and the second support are flat or cup-shaped.

The disclosure also provides support for a heat exchanger, comprising: a baseplate comprising a first port and a second port, a heat transfer element coupled to the baseplate at a location between the first port and the second port, a core plate configured to couple to the baseplate and house the heat transfer element, and at least one support pressed against the core plate and arranged between an extreme end of the heat transfer element and a short side of the core plate. In a first example of the system, the at least one support is a first support, the extreme end is a first extreme end, and the short side is a first short side, further comprising a second support arranged between a second extreme end of the heat exchanger element and a second short side of the core plate. In a second example of the system, optionally including the first example, the at least one support comprises a top surface, a long side, a first short side, and a second short side opposite the first short side, wherein the top surface is in contact with each of the long side, the first short side, and the second short side. In a third example of the system, optionally including one or both of the first and second examples, an entirety of the long side is in face-sharing contact with the short side of the core plate. In a fourth example of the system, optionally including one or more or each of the first through third examples, the first short side is in face-sharing contact with a portion of a first long side of the core plate, and the second short side is in face-sharing contact with a portion of a second long side of the core plate, the second long side opposite the first long side. In a fifth example of the system, optionally including one or more or each of the first through fourth examples, long sides of the core plate and short sides of the at least one support are indented. In a sixth example of the system, optionally including one or more or each of the first through fifth examples, the at least one support is a plate and is retained via a plurality of tabs against the core plate. In a seventh example of the system, optionally including one or more or each of the first through sixth examples, the at least one support is retained flush against the core plate.

The disclosure also provides support for a heat exchanger, comprising: a heat transfer element housed between a baseplate and a core plate, and a first support and a second support arranged between the heat transfer element and short sides of the core plate, wherein a long axis of the first support and the second support is normal to a long axis of the core plate. In a first example of the system, the first support and the second support are identical in size and shape, and wherein a shape of the first support and the second support match a shape of the core plate corresponding to a location at which the heat transfer element is not present. In a second example of the system, optionally including the first example, the first support and the second support are retained against the core plate via a plurality of indentations or a plurality of tabs. In a third example of the system, optionally including one or both of the first and second examples, a top surface of the first support and the second support is pressed against the core plate and distal to the baseplate. In a fourth example of the system, optionally including one or more or each of the first through third examples, the first support and the second support are a single piece and smooth along each surface thereof.

In some examples, additionally or alternatively, the support 920 may be retained via indentations, welds, or other coupling elements.

As used herein, the term “approximately” is construed to mean plus or minus five percent of the range unless otherwise specified.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A heat exchanger, comprising:
a first support and a second support arranged on opposite sides of a heat transfer element and in face-sharing contact with a core plate.

2. The heat exchanger of claim 1, wherein the first support and the second support are retained against the core plate via indentations.

3. The heat exchanger of claim 1, wherein the first support and the second support are retained via a plurality of tabs against the core plate.

4. The heat exchanger of claim 1, wherein the first support and the second support are brazed to the core plate.

5. The heat exchanger of claim 1, wherein the first support and the second support are identical in size and shape.

6. The heat exchanger of claim 1, wherein the first support and the second support comprise a cutout corresponding to ports of the core plate.

7. The heat exchanger of claim 1, the first support and the second support are flat or cup-shaped.

8. A heat exchanger, comprising:
a baseplate comprising a first port and a second port;
a heat transfer element coupled to the baseplate at a location between the first port and the second port;
a core plate configured to couple to the baseplate and house the heat transfer element; and
at least one support pressed against the core plate and arranged between an extreme end of the heat transfer element and a short side of the core plate.

9. The heat exchanger of claim 8, wherein the at least one support is a first support, the extreme end is a first extreme end, and the short side is a first short side, further comprising a second support arranged between a second extreme end of the heat transfer element and a second short side of the core plate.

10. The heat exchanger of claim 8, wherein the at least one support comprises a top surface, a long side, a first short side, and a second short side opposite the first short side, wherein the top surface is in contact with each of the long side, the first short side, and the second short side.

11. The heat exchanger of claim 10, wherein an entirety of the long side is in face-sharing contact with the short side of the core plate.

12. The heat exchanger of claim 10, wherein the first short side is in face-sharing contact with a portion of a first long side of the core plate, and the second short side is in face-sharing contact with a portion of a second long side of the core plate, the second long side opposite the first long side.

13. The heat exchanger of claim 8, wherein long sides of the core plate and short sides of the at least one support are indented.

14. The heat exchanger of claim 8, wherein the at least one support is a plate and is retained via a plurality of tabs against the core plate.

15. The heat exchanger of claim 8, wherein the at least one support is retained flush against the core plate.

16. A heat exchanger, comprising:
a heat transfer element housed between a baseplate and a core plate; and
a first support and a second support arranged between the heat transfer element and short sides of the core plate, wherein a long axis of the first support and the second support is normal to a long axis of the core plate.

17. The heat exchanger of claim 16, wherein the first support and the second support are identical in size and shape, and wherein a shape of the first support and the second support match a shape of the core plate corresponding to a location at which the heat transfer element is not present.

18. The heat exchanger of claim 16, wherein the first support and the second support are retained against the core plate via a plurality of indentations or a plurality of tabs.

19. The heat exchanger of claim 16, wherein a top surface of the first support and the second support is pressed against the core plate and distal to the baseplate.

20. The heat exchanger of claim 16, wherein the first support and the second support are a single piece and smooth along each surface thereof.
